(19) United States
(12) Patent Application Publication
(10) Pub. No.: US 2024/0379679 A1
(43) Pub. Date: Nov. 14, 2024

(54) THREE-DIMENSIONAL (3D) DUAL COMPLEMENTARY CIRCUIT STRUCTURES AND RELATED FABRICATION METHODS

(71) Applicant: QUALCOMM Incorporated, San Diego, CA (US)

(72) Inventors: Xia Li, San Diego, CA (US); Junjing Bao, San Diego, CA (US); Jun Yuan, San Diego, CA (US)

(21) Appl. No.: 18/314,245

(22) Filed: May 9, 2023

(51) Int. Cl. H01L 27/092; H01L 21/822; H01L 21/8238; H01L 29/06; H01L 29/417; H01L 29/423; H01L 29/49; H01L 29/66; H01L 29/775

(52) U.S. Cl. CPC H01L 27/0922; H01L 21/8221; H01L 21/823807; H01L 21/823842; H01L 21/823871; H01L 29/0673; H01L 29/41733; H01L 29/42392; H01L 29/4908; H01L 29/66439; H01L 29/66545; H01L 29/775

(57) ABSTRACT

A 3D dual complementary-circuit structure includes a first forksheet structure stacked on a first side of, in a first direction, a second forksheet structure to provide two complementary circuits in a space of a single forksheet structure. A dividing wall bisects at least one semiconductor slab in the first forksheet structure into a first slab portion with a first semiconductor type and a second slab portion with a second semiconductor type and also bisects at least one semiconductor slab in the second forksheet structure into a third slab portion with a third semiconductor type and a fourth slab portion with a fourth semiconductor type. One of the second semiconductor type, the third semiconductor type, and the fourth semiconductor type may be a same semiconductor type as the first semiconductor type. Two complementary metal oxide semiconductor (CMOS) circuits may be formed in the area of a single forksheet structure.

### BACKGROUND

### I. Field of the Disclosure

The technology of the disclosure relates generally to transistors in integrated circuits and, more particularly, to three-dimensional transistor circuits.

### II. Background

Consumer demand for higher electronic device performance drives technological advancement. For example, there is an ongoing trend towards increasing the number of transistors in integrated circuits (ICs) in electronic devices, such as cell phones, laptops, and tablets, in response to consumer demand for devices having greater functionality and performance in a smaller package. Reducing the sizes of transistors allows more transistors to fit on a chip having a same area or allows the same number of transistors to fit on a smaller chip. One method for reducing the area of individual transistors involves trading horizontal area for vertical height. This has prompted the development of three-dimensional (3D) transistors and circuits. For example, a complementary circuit employing two different types of transistors can be reduced by vertically stacking a first type transistor on a second type transistor. However, in addition to the sizes of individual transistors, another contributor to the area of an IC is a minimum side-to-side spacing distance between transistors due to a limitation of fabrication processes. Due to this spacing distance, a large percentage of the area of an IC chip is wasted. Methods of further reducing an area occupied by a plurality of transistors are needed.

### SUMMARY

Aspects disclosed in the detailed description include three-dimensional (3D) dual complementary circuit structures. Related methods of fabricating 3D dual complementary circuit structures are also disclosed. An exemplary 3D dual complementary-circuit structure includes a first forksheet structure stacked on a first side in a first direction of a second forksheet structure to provide two complementary circuits in a space of a single forksheet structure. Forksheet structures include at least one semiconductor slab, employed as a transistor channel, that is bisected by a dividing wall to form a first circuit device in a first slab portion and a second circuit device in a second slab portion to provide two circuit devices in an area smaller than two separate circuit device structures. The dividing wall divides at least one semiconductor slab in the first forksheet structure into a first slab portion with a first semiconductor type and a second slab portion with a second semiconductor type and also divides at least one semiconductor slab in the second forksheet structure into a third slab portion with a third semiconductor type and a fourth slab portion with a fourth semiconductor type. In this manner, two CMOS circuits may be formed in one of a plurality of configurations within the area of a single forksheet structure to significantly increase circuit density and reduce area of an integrated circuit.

Any one of the second semiconductor type, the third semiconductor type, and the fourth semiconductor type may be the same semiconductor type as the first semiconductor type. In some examples, only one of the second semiconductor type, the third semiconductor type, and the fourth semiconductor type may be the same semiconductor type as the first semiconductor type, while the others may be an opposite semiconductor type. In such examples, in which the 3D dual complementary-circuit structure has two semiconductor devices of each semiconductor type, two complementary metal oxide semiconductor (CMOS) circuits may be formed in the area of the first forksheet structure, which is an area smaller than an area of two separate device structures.

In this regard, in one aspect, a 3D dual circuit structure is disclosed. The 3D dual circuit structure includes a first forksheet structure comprising at least one first semiconductor slab, a second forksheet structure comprising at least one second semiconductor slab and disposed on a first side of, in a first direction, the first forksheet structure, and a dividing wall bisecting the at least one first semiconductor slab in a second direction orthogonal to the first direction into a first slab portion comprising a first semiconductor type on a first side of the dividing wall and a second slab portion comprising a second semiconductor type on a second side of the dividing wall, and also bisecting the at least one second semiconductor slab in the second direction into a third slab portion comprising a third semiconductor type on the first side of the dividing wall and a fourth slab portion comprising a fourth semiconductor type on the second side of the dividing wall, wherein a first one of the second semiconductor type, the third semiconductor type, and the fourth semiconductor type is the same semiconductor type as the first semiconductor type.

In another aspect, a method of fabricating a 3D dual circuit structure is disclosed. The method of fabricating a 3D dual circuit structure includes forming a first forksheet structure comprising at least one first semiconductor slab, forming a second forksheet structure comprising at least one second semiconductor slab and disposed on a first side of, in a first direction, the first forksheet structure, and forming a dividing wall bisecting the at least one first semiconductor slab in a second direction orthogonal to the first direction into a first slab portion comprising a first semiconductor type on a first side of the dividing wall and a second slab portion comprising a second semiconductor type on a second side of the dividing wall and also bisecting the at least one second semiconductor slab in the second direction into a third slab portion comprising a third semiconductor type on the first side of the dividing wall and a fourth slab portion comprising a fourth semiconductor type on the second side of the dividing wall, wherein a first one of the second semiconductor type, the third semiconductor type, and the fourth semiconductor type is the same semiconductor type as the first semiconductor type.

In another aspect, an integrated circuit (IC) is disclosed. The IC includes complementary logic circuits comprising a plurality of 3D dual circuit structures, each of the 3D dual circuit structures comprising a first forksheet structure comprising at least one first semiconductor slab, a second forksheet structure comprising at least one second semiconductor slab, and disposed on a first side of, in a first direction, the first forksheet structure, and a dividing wall bisecting the at least one first semiconductor slab in a second direction orthogonal to the first direction into a first slab portion comprising a first semiconductor type on a first side of the dividing wall and a second slab portion comprising a second semiconductor type on a second side of the dividing wall and also bisecting the at least one second semiconductor slab in the second direction into a third slab portion comprising a third semiconductor type on the first side of the dividing wall and a fourth slab portion comprising a fourth semiconductor type on the second side of the dividing wall, wherein a first one of the second semiconductor type, the third semiconductor type, and the fourth semiconductor type is the same semiconductor type as the first semiconductor type.

### BRIEF DESCRIPTION OF THE DRAWINGS

FIG. 1A is a top view of one example of an exemplary three-dimensional (3D) dual complementary-circuit structure that includes stacked forksheet structures in which two complementary metal-oxide semiconductor (CMOS) circuits are formed in an area of a forksheet structure;

FIG. 1B is a cross-sectional side view of the exemplary 3D dual complementary-circuit structure in FIG. 1A, illustrating the forksheet structures divided into respective slab portions;

FIG. 1C is a cross-sectional side view along the channel direction of the first forksheet and the second forksheet in the exemplary 3D dual complementary-circuit structure in FIG. 1A;

FIG. 2 is a flowchart illustrating an exemplary fabrication process for fabricating the exemplary 3D dual complementary-circuit structure, including stacked forksheet structures in which two CMOS circuits are formed in a reduced area, including but not limited to the dual complementary-circuit structure in FIGS. 1A-1C;

FIG. 3A-3I is a flowchart illustrating another exemplary fabrication process of fabricating an exemplary dual complementary-circuit structure, including stacked forksheet structures in which two CMOS circuits are formed in an area of a forksheet structure, including but not limited to the dual complementary-circuit structure in FIGS. 1A-1C;

FIGS. 4A-4I are exemplary fabrication stages during the fabrication of an exemplary 3D dual complementary-circuit structure, including stacked forksheet structures in which two CMOS circuits are formed in an area of a forksheet structure, according to the exemplary fabrication process in FIGS. 1A-1C;

FIG. 5 is a cross-sectional side view of another example of a 3D dual complementary-circuit structure, including stacked forksheet structures in which two CMOS circuits are formed in an area of a forksheet structure, having gates in the first forksheet structure coupled to gates in the second forksheet structure and gate contacts on only one side;

FIG. 6 is a cross-sectional side view of another example of a 3D dual complementary-circuit structure, including stacked forksheet structures in which two CMOS circuits are formed in an area of a forksheet structure, having gates in the first forksheet structure coupled to gates in the second forksheet structure and gate contacts on both sides;

FIG. 7 is a cross-sectional side view of another example of a 3D dual complementary-circuit structure, including stacked forksheet structures in which two CMOS circuits are formed in an area of a forksheet structure, having gates in the first forksheet structure coupled to each other and gates in the second forksheet structure coupled to each other;

FIG. 8 is a block diagram of an exemplary wireless communication device that includes radio-frequency (RF) components that can include the 3D dual complementary-circuit structure, including stacked forksheet structures in which two CMOS circuits are formed in an area of a forksheet structure, including but not limited to the 3D dual circuit structure in FIGS. 1A-1C and 5-7 and according to, but not limited to, any of the exemplary fabrication processes in FIGS. 2 and 3A-3I; and

FIG. 9 is a block diagram of an exemplary processor-based system that can include the 3D dual complementary-circuit structure, including stacked forksheet structures in which two CMOS circuits are formed in a reduced area, including but not limited to the dual circuit structure in FIGS. 1A-1C and 5-7 and according to, but not limited to, any of the exemplary fabrication processes in FIGS. 2 and 3A-3I.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include three-dimensional (3D) dual complementary circuit structures. Related methods of fabricating 3D dual complementary circuit structures are also disclosed. An exemplary 3D dual complementary-circuit structure includes a first forksheet structure stacked on a first side in a first direction of the second forksheet structure to provide two complementary circuits in a space of a single forksheet structure. Forksheet structures include at least one semiconductor slab, employed as a transistor channel, that is bisected by a dividing wall to form a first circuit device in a first slab portion and a second circuit device in a second slab portion to provide two circuit devices in an area smaller than two separate circuit device structures. The dividing wall divides the at least one semiconductor slab in the first forksheet structure into a first slab portion with a first semiconductor type and a second slab portion with a second semiconductor type and also divides at least one semiconductor slab in the second forksheet structure into a third slab portion with a third semiconductor type and a fourth slab portion with a fourth semiconductor type. In this manner, two CMOS circuits may be formed in one of a plurality of configurations within the area of a single forksheet structure to significantly increase circuit density and reduce area of an integrated circuit.

Any one of the second semiconductor type, the third semiconductor type, and the fourth semiconductor type may be the same semiconductor type as the first semiconductor type. In some examples, only one of the second semiconductor type, the third semiconductor type, and the fourth semiconductor type may be the same semiconductor type as the first semiconductor type, while the others may be an opposite semiconductor type. In such examples, in which the 3D dual complementary-circuit structure has two semiconductor devices of each semiconductor type, two complementary metal oxide semiconductor (CMOS) circuits may be formed in the area of a first forksheet structure, which is an area smaller than an area of two separate device structures.

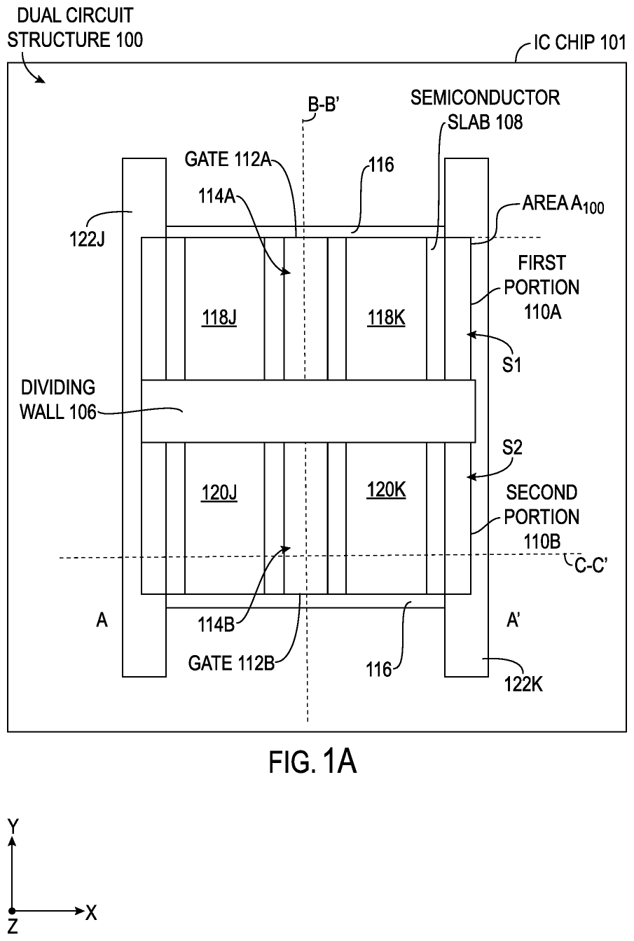

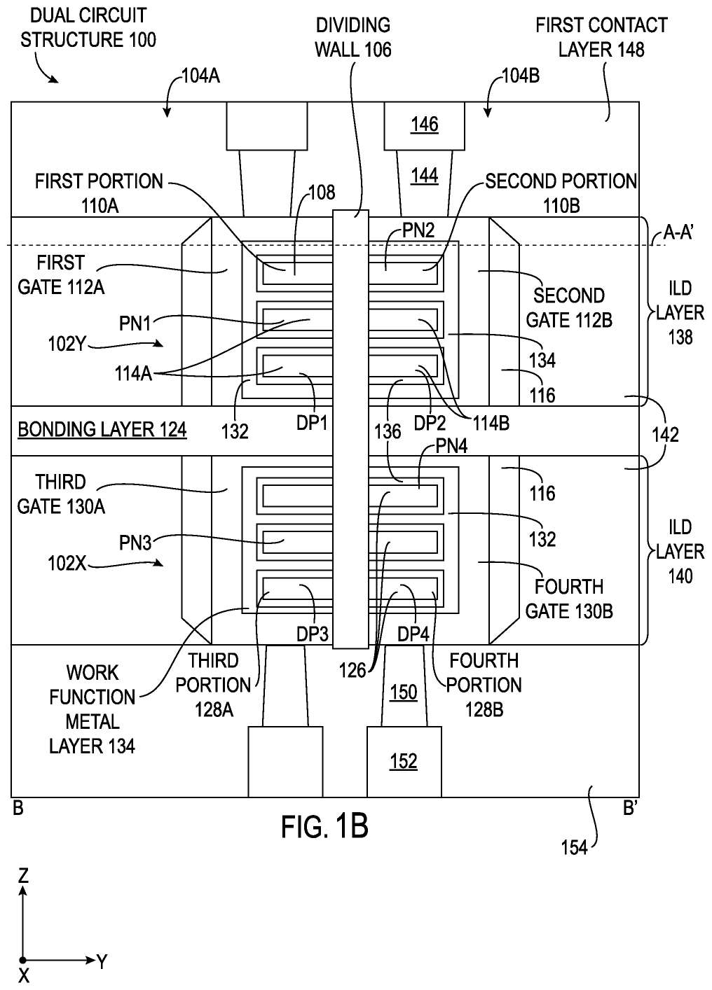

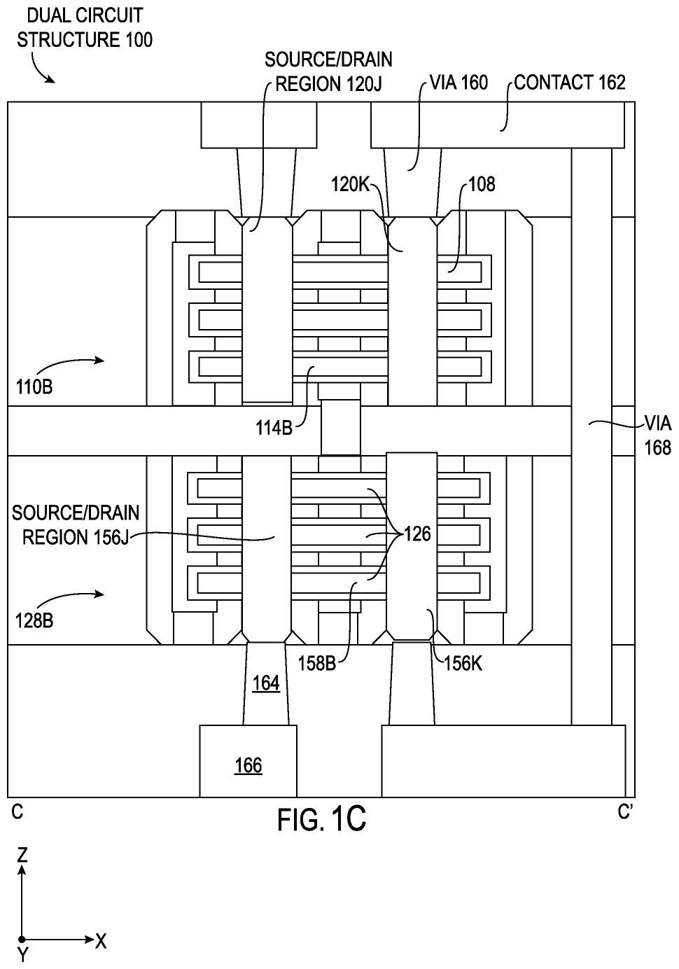

In this regard, FIG. 1A is a top view of one example of an exemplary three-dimensional (3D) dual complementary-circuit structure (“dual circuit structure”) 100 on an integrated circuit chip (IC) 101 and a first forksheet structure 102Y, which is stacked in a first, vertical direction (Z-axis, direction) on a second forksheet structure 102X (not shown in FIG. 1A) to provide a first and second complementary metal-oxide semiconductor (CMOS) circuits 104A and 104B in an area A₁₀₀ of a forksheet extending in a second, horizontal direction (X-axis direction) and a third, horizontal direction (Y-axis direction). A semiconductor slab is a thin layer having two opposing flat, planar faces and two edges. A semiconductor slab bisected by a dividing wall is divided or split through the two faces into a first slab portion on a first side of the dividing wall and a second slab portion on the second side of the dividing wall separate from each other. The first slab portion and the second slab portion are electrically isolated from each other due to the bisecting but may be otherwise coupled. The first portion and the second portion may be unequal in size. The bisected semiconductor slab in the forksheet structure provides two circuit devices in an area that is smaller than two circuit device structures with transistor channel regions formed separately. Features referred to herein are shown in FIGS. 1A, 1B, and 1C, which are each illustrations of the dual circuit structure 100, and in some instances, features may only be shown in one of FIGS. 1A, 1B, and 1C.

The second, X-axis direction and the third, Y-axis direction, are each orthogonal to the first direction and to each other. The area A₁₀₀ can be smaller than an area of two separate device structures (e.g., complementary field effect transistor (CFET) structures) spaced apart at a minimum separation distance as determined by fabrication process limitations because respective portions of the first and second stacked forksheet structures 102Y and 102X are separated by a dividing wall 106, which is narrower in width than the minimum separation distance. As an example, the first CMOS circuit 104A may be formed on a first side S1 of the dividing wall 106, and the second CMOS circuit 104B may be formed on a second side S2 of the dividing wall 106. However, other configurations are possible. A CMOS circuit includes a first circuit device having a first semiconductor type and a second circuit device having an opposite semiconductor type, as explained further below.

The first forksheet structure 102Y includes at least one first semiconductor slab (e.g., nanosheet) 108, which is split into a first slab portion 110A and a second slab portion 110B by the dividing wall 106, which are also referred to herein as first portion 110A and second portion 110B. The dual circuit structure 100 also includes a first gate 112A disposed around the first portion 110A of the at least one first semiconductor slab 108 and a second gate 112B disposed around the second portion 110B of the at least one first semiconductor slab 108. The first gate 112A and the second gate 112B may initially be formed as a single structure but are split by the addition of the dividing wall 106. The first gate 112A controls current flow in the second, X-axis direction in a first channel region 114A of the first portion 110A of the first semiconductor slab 108. The second gate 112B controls current flow in a second channel region 114B in the second portion 110B of the first semiconductor slab 108. Thus, circuit devices, such as metal-oxide-semiconductor (MOS) transistors, may be formed in the first portion 110A and the second portion 110B of the first forksheet structure 102Y. The dual circuit structure 100 also includes spacers 116 on each side of the first forksheet structure 102Y.

On either side of the first gate 112A, in the second direction, the first portion 110A of the first semiconductor slab 108 is coupled to source/drain regions 118J and 118K, and the second portion 110B of the semiconductor slab 108 is coupled to source/drain regions 120J and 120K. Currents in the first portion 110A and the second portion 110B of the semiconductor slab 108 are based, in part, on voltage differentials between the source/drain regions 118J, 118K and between the source/drain regions 120J, 120K, respectively. The dual circuit structure 100 also includes dummy gates 122J and 122K at either end (in the second direction) of the first portion 110A and the second portion 110B of the semiconductor slab 108. In some examples, the dummy gates 122J and 122K are inactive gates that isolate the dual circuit structure 100 from other circuit structures and may be active gates to control current flow in other channel regions.

FIG. 1B is a cross-sectional side view of the dual circuit structure 100 taken at the cross-section B-B′ in FIG. 1A, which extends in the third, Y-axis direction through the gates 112A and 112B and across (e.g., orthogonal to) the dividing wall 106. The cross-section B-B′ is taken in a plane extending in the third direction (Y-axis direction) and the first direction (Z-axis direction). The top view in FIG. 1A is at a cross-section A-A′ shown in FIG. 1B.

FIG. 1B shows that the at least one first semiconductor slab 108 in the first forksheet structure 102Y includes three first semiconductor slabs in this example. The current drive capability of the first channel region 114A of the first portion 110A and the second channel region 114B of the second portion 110B is determined, at least in part, by a number of the at least one first semiconductor slab 108, and there may be more or less than the number shown here.

FIG. 1B also shows the second forksheet structure 102X disposed on a first side of (e.g., below), in the first direction, the first forksheet structure 102Y. The second forksheet structure 102X is structurally similar in many aspects but inverted with respect to the first forksheet structure 102Y. In other words, the first forksheet structure 102Y and the second forksheet structure 102X may be, in some structural aspects, mirror images of each other in the first direction, on opposite sides of a bonding layer 124 that separates them. In some examples, the bonding layer 124 may comprise a shallow trench isolation (STI) material layer.

The second forksheet structure 102X includes at least one (e.g., three in this example) second semiconductor slab 126 divided into a third portion 128A and a fourth portion 128B, which are electrically isolated from each other by the dividing wall 106. The second forksheet structure 102X includes a third gate 130A and a fourth gate 130B, which are also electrically separated from each other by the dividing wall 106. The first and second gates 112A, 112B and the third and fourth gates 130A, 130B are made of a conductive material, such as metal.

The at least one first semiconductor slab 108 and the at least one second semiconductor slab 126 are formed from a semiconductor material, such as silicon (Si). In the first portion 110A of the first forksheet structure 102Y, the semiconductor material is doped with a first dopant DP1 to have a first semiconductor type PN1. In the third portion 128A of the second forksheet structure 102X, the semiconductor material is doped with a third dopant DP3 to have a third semiconductor type PN3 which, in this example, is opposite to the first semiconductor type PN1. For example, the first semiconductor type PN1 may be doped with a pentavalent dopant, and the third semiconductor type PN3 may be doped with a trivalent dopant. In another example, the first semiconductor type PN1 is doped with a trivalent dopant, and the third semiconductor type is doped with a pentavalent dopant. In other examples, the first semiconductor type PN1 in the first portion 110A and the third semiconductor type PN3 in the third portion 128A are the same semiconductor type.

Depending on the dopant types, the semiconductor material in each of the at least one first semiconductor slab 108 in the first portion 110A and the at least one second semiconductor slab 126 in the third portion 128A is either an N-type semiconductor or a P-type semiconductor. Thus, in this example, in which the first semiconductor type PN1 of the first portion 110A and the third semiconductor type PN3 of the third portion 128A are opposite semiconductor types, a first CMOS circuit 104A may be formed. The at least one first semiconductor slab 108 in the second portion 110B of the first forksheet structure 102Y is doped by a second dopant DP2 for a second semiconductor type PN2 which, in this example, is opposite to the first semiconductor type PN1 and also opposite to the fourth semiconductor type PN4 of the at least one second semiconductor slab 126B in the fourth portion 128B doped with a fourth dopant DP4. In this manner, the second portion 110B and the fourth portion 128B, can be employed to form the second CMOS circuit 104B.

In some examples, the first semiconductor type PN1 of the first portion 110A is the same as the second semiconductor type PN2 of the second portion 110B. In some examples, the first semiconductor type PN1 of the first portion 110A is the same as the third semiconductor type PN3 of the third portion 128A. In some examples, the first semiconductor type PN1 of the first portion 110A, is the same as the fourth semiconductor type PN4 of the fourth portion 128B. In some examples, any two of the first semiconductor type PN1, the second semiconductor type PN2, the third conductor type PN3, and the fourth semiconductor type PN4 are P-type semiconductors, and the other two are N-type semiconductors, such that two CMOS circuits may be formed in the dual circuit structure 100.

It can be seen in FIG. 1B that the first gate 112A is disposed around the at least one first semiconductor slab 108 in the first portion 110A, in a manner resembling a gate-all-around (GAA) type transistor, except where the dividing wall 106 abuts the at least one first semiconductor slab 108. The second gate 112B, the third gate 130A, and the fourth gate 130B are also disposed around the sides of the at least one semiconductor slabs 108 and 126 except where abutted by the dividing wall 106. In addition, work function metal layers 132 and 134 are disposed around the at least one first semiconductor slab 108 and 126. In particular, the work function metal layer 132 is a type of work functional metal that corresponds to the first semiconductor type PN1 and the fourth semiconductor type PN4 in the example in FIG. 1B. Thus, the work function metal layer 132 is disposed between the at least one first semiconductor slab 108 in the first portion 110A and the first gate 112A. The work function metal layer 132 is also disposed between the at least one second semiconductor slab 126 in the fourth portion 128B and the fourth gate 130B. The work function metal layer 134 corresponds to the second semiconductor type PN2 and the third semiconductor type PN3, as shown in FIG. 1B. Thus, the work function metal layer 134 is disposed between the at least one first semiconductor slab 108 in the second portion 110B and the second gate 112B and also disposed between the at least one second semiconductor slab 126 in the third portion 128A and the third gate 130A. The work function metal layers 132 and 134 are separated from the at least one semiconductor slabs 108 and 126 by a dielectric layer 136.

Structurally, the first forksheet structure 102Y and the second forksheet structure 102X are disposed in inter-layer dielectric (ILD) layers 138 and 140, respectively, of an ILD material 142 or other suitable material. The first and second gates 112A, 112B of the first forksheet structure 102Y and the third and fourth gates 130A, 130B of the second forksheet structure 102X are isolated from the ILD material 142 by the spacers 116. For example, the dividing wall 106 and the spacers 116 may be formed of silicon nitride (SiN or SiO2). The materials used for the work function metal layers 132 and the work function metal layers 134 are selected according to whether the semiconductor types PN1, PN2, PN3, and PN4 are N-type or P-type.

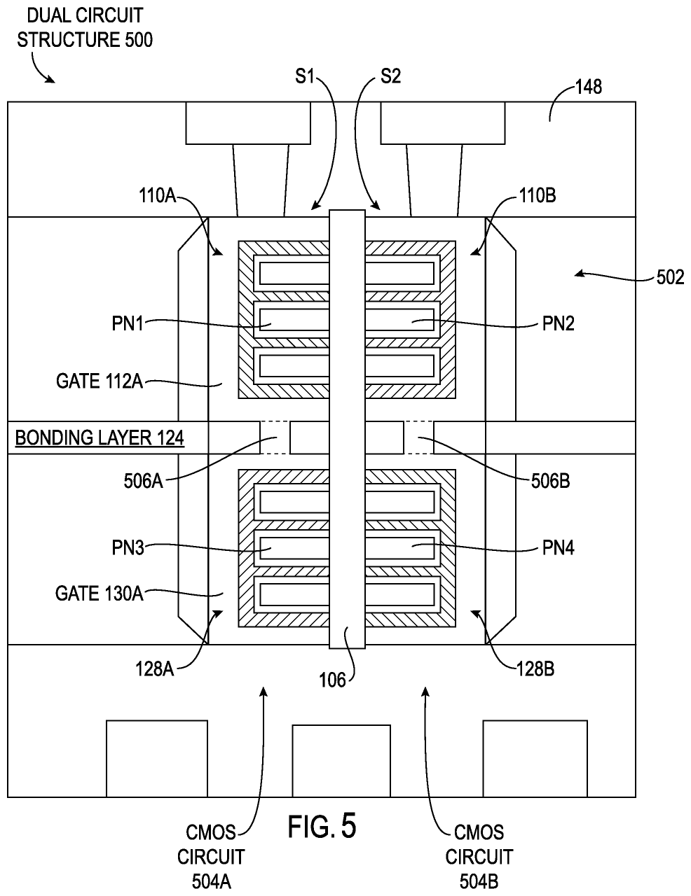

To electrically couple to/from an external circuit, the dual circuit structure 100 includes vias 144 and contacts 146 in a first contact layer 148 to separately supply controlling voltages to control current flow in the first and second channel regions 114A. 114B. Vias 150 and contacts 152 in a second contact layer 154 are used to provide supply voltages to control current flow in the third portion 128A and the fourth portion 128B. Thus, in this example, each of the first gate 112A, the second gate 112B, the third gate 130A, and the fourth gate 130B are individually controlled by separate control voltages provided at the contacts 146 and 152. However, depending on circuit needs, the control voltages may be applied with different configurations, as shown by examples in FIGS. 5-7, discussed below.

FIG. 1C is a cross-sectional side view of a cross-section C-C′ in FIG. 1A of the dual circuit structure 100. The cross-section C-C′ extends in the first direction (Z-axis direction and also in the second direction (X-axis direction), which is the direction of current flow in the at least one first semiconductor slab 108 in the second portion 110B and the at least one second semiconductor slab 126 in the fourth portion 128B. Features common to FIGS. 1B and 1C may have the same labels and are not described again here. Some of the features referred to in this description are shown in FIG. 1A or 1B.

FIG. 1C is provided to show that the source/drain regions 120J and 120K in the second portion 110B extend in the first, X-axis direction and are coupled to each of the at least one first semiconductor slab 108 and source/drain regions 156J and 156K in the second portion 110B extend in the first, X-axis direction and are coupled to each of the at least one second semiconductor slab 126. It should be understood that the source/drain regions 120J, 120K, 156J, and 156K are in the first through fourth source/drain regions of the dual circuit structure 100 on the second side S2 of the dividing wall 106 (see FIG. 1A) and there are fifth, sixth, seventh, and eighth source/drain regions (not shown) similarly coupled to the at least one first semiconductor slab 108 in the first portion 110A and the at least one second semiconductor slab 126 in the third portion 128A. In this example, the fifth to eighth source/drain regions would also be coupled to the fifth to eighth contacts in the first contact layer 148 and the second contact layer 154.

The source/drain region 120J and the source/drain region 120K are on opposite sides of the channel region 114B to provide a source and a drain of a transistor, according to the polarity of the voltage applied between the source/drain region 120J and the source/drain region 120K. Source/drain regions 156J and 156K extend in the first direction in the fourth portion 128B and are coupled to each of the at least one second semiconductor slab 126. The source/drain regions 156J and 156K provide a source and a drain on either of a channel region 158B in a transistor (e.g., MOS transistor), according to a polarity of applied voltage.

The source/drain regions 120J and 120K are coupled to metal vias 160 and metal contacts 162, and the source/drain regions 156J and 156K are coupled to metal vias 164 and metal contacts 166. The dual circuit structure 100 in this example includes a via 168 to electrically couple the source/drain region 120K of the second portion 110B to the source/drain region 156K of the fourth portion 128B, which can be used to configure an inverter circuit or other circuit in which a source/drain region of a transistor of a first type is coupled to a source/drain region of a transistor of a second type.

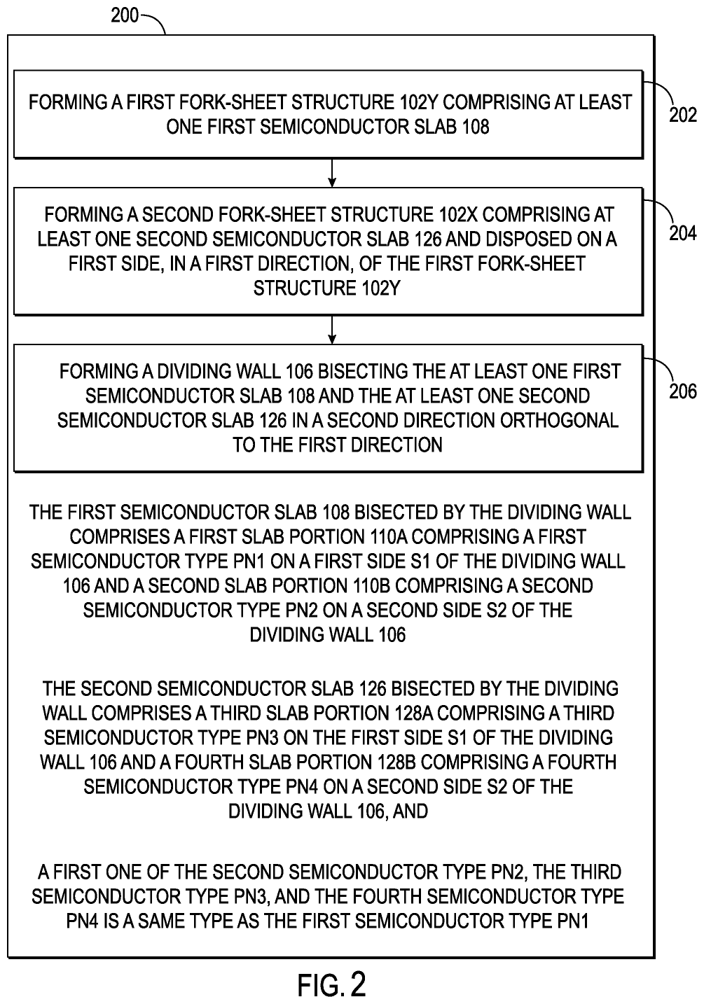

Fabrication processes can be employed to fabricate a dual circuit structure, including a 3D forksheet structure in which two CMOS circuits are formed in a reduced area, including but not limited to the dual circuit structure 100 in FIGS. 1A-1C. In this regard, FIG. 2 is a flowchart illustrating an exemplary fabrication process 200 of fabricating a dual complementary-circuit structure, including a 3D forksheet stack in which two CMOS circuits are formed in a reduced area. The fabrication process 200 in FIG. 2 is discussed with regard to the dual circuit structure 100 in FIGS. 1A-1C, but note that the fabrication process 200 in FIG. 2 is not limited to fabricating a dual circuit structure 100 in FIGS. 1A-1C.

In this regard, an exemplary step in fabricating the dual circuit structure 100 includes forming a first forksheet structure 102Y comprising at least one first semiconductor slab 108 (block 202); forming a second forksheet structure, 102X comprising at least one second semiconductor slab 126 and disposed on a first side, in a first direction, of the first forksheet structure 102Y (block 204). The method includes forming a dividing wall 106 bisecting the at least one first semiconductor slab 108 and the at least one second semiconductor slab 126 in a second direction orthogonal to the first direction (block 206), wherein: the first semiconductor slab 108 bisected by the dividing wall comprises a first slab portion 110A comprising a first semiconductor type PN1 on a first side S1 of the dividing wall 106 and a second slab portion 110B comprising a second semiconductor type PN2 on a second side S2 of the dividing wall 106; the second semiconductor slab 126 bisected by the dividing wall comprises a third slab portion 128A comprising a third semiconductor type PN3 on the first side S1 of the dividing wall 106 and a fourth slab portion 128B comprising a fourth semiconductor type PN4 on the second side S2 of the dividing wall 106; and a first one of the second semiconductor type PN2, the third semiconductor type PN3, and the fourth semiconductor type PN4 is the same type as the first semiconductor type PN1.

Other fabrication processes can also be employed to fabricate a dual circuit structure, including a 3D forksheet stack in which two CMOS circuits are formed in a reduced area, including but not limited to the dual circuit structure 100 in FIGS. 1A-1C.

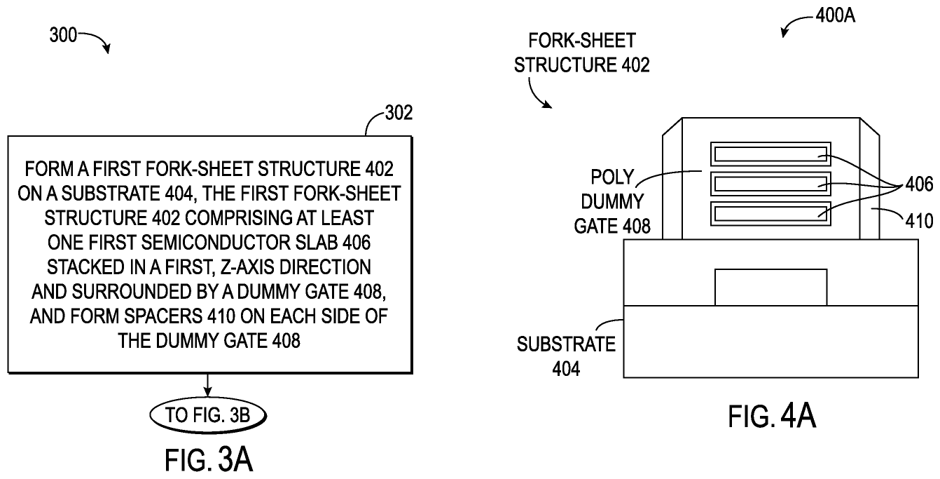

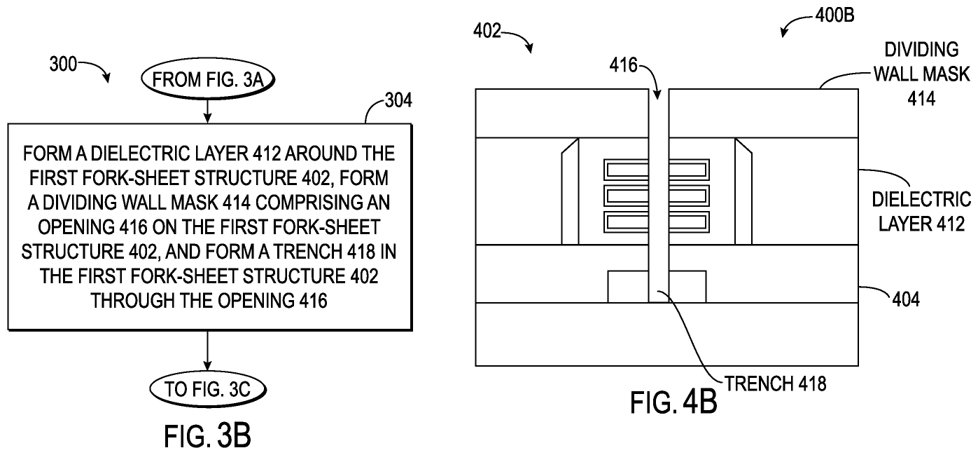

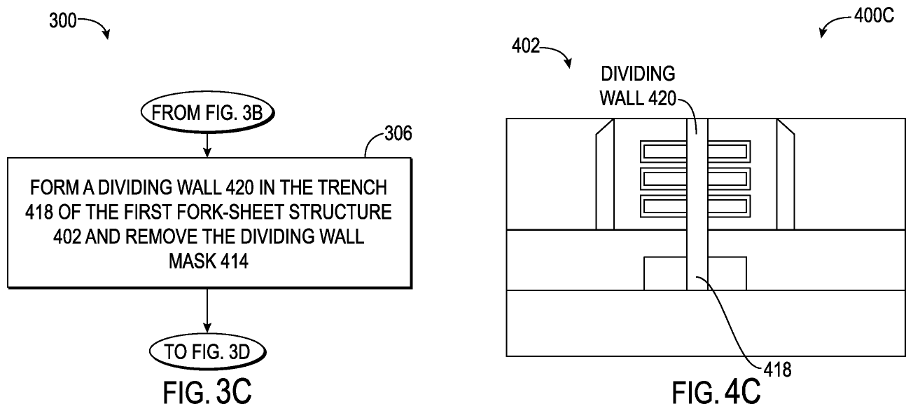

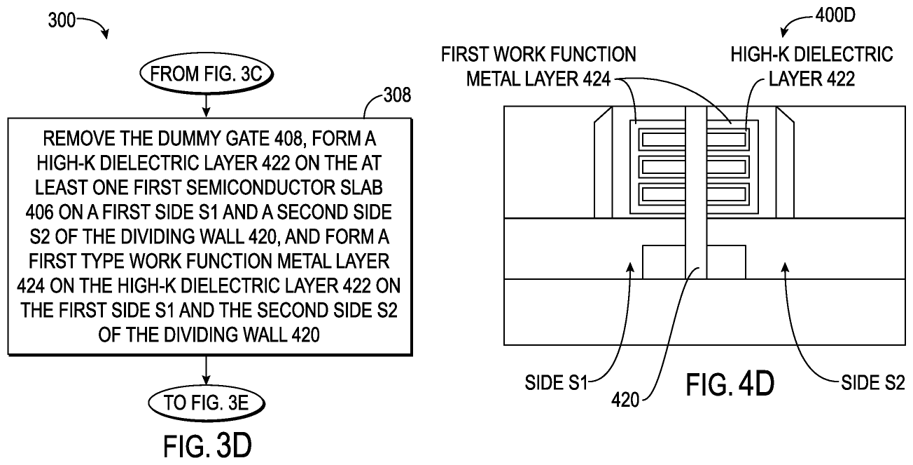

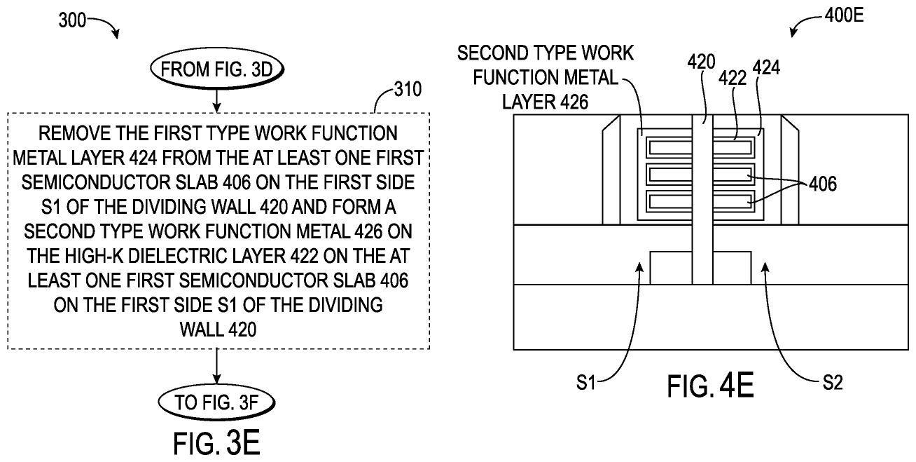

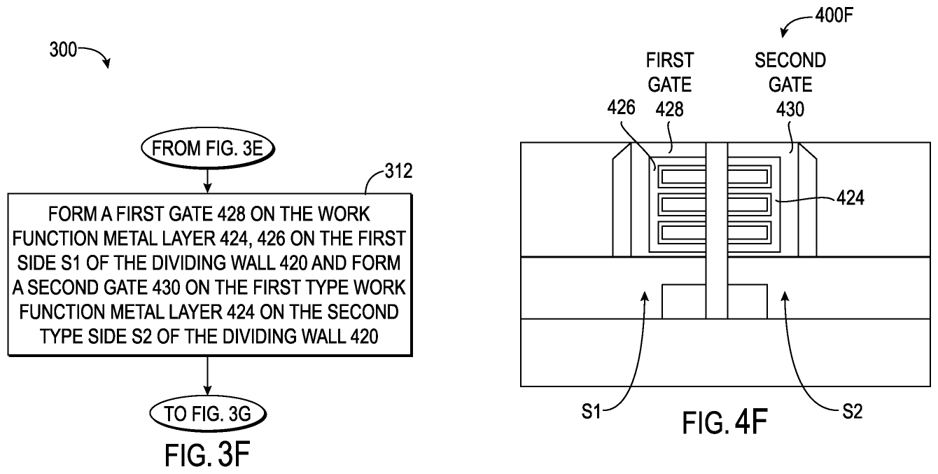

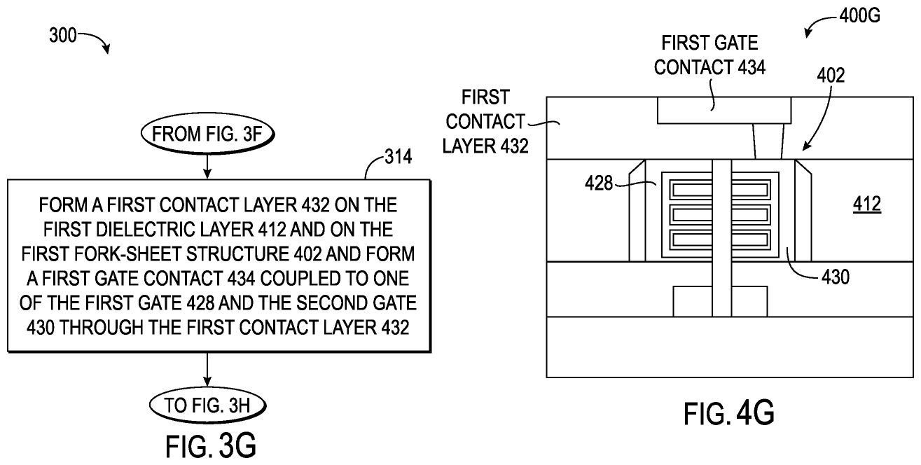

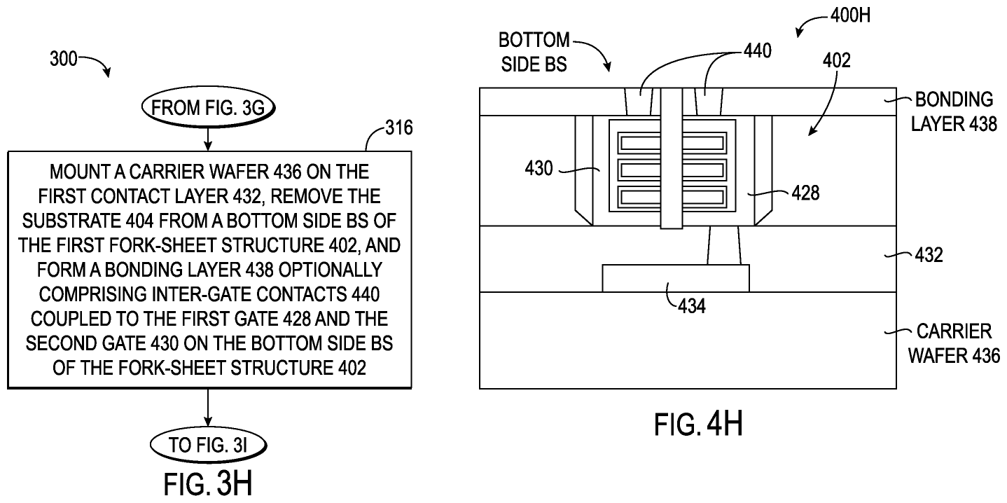

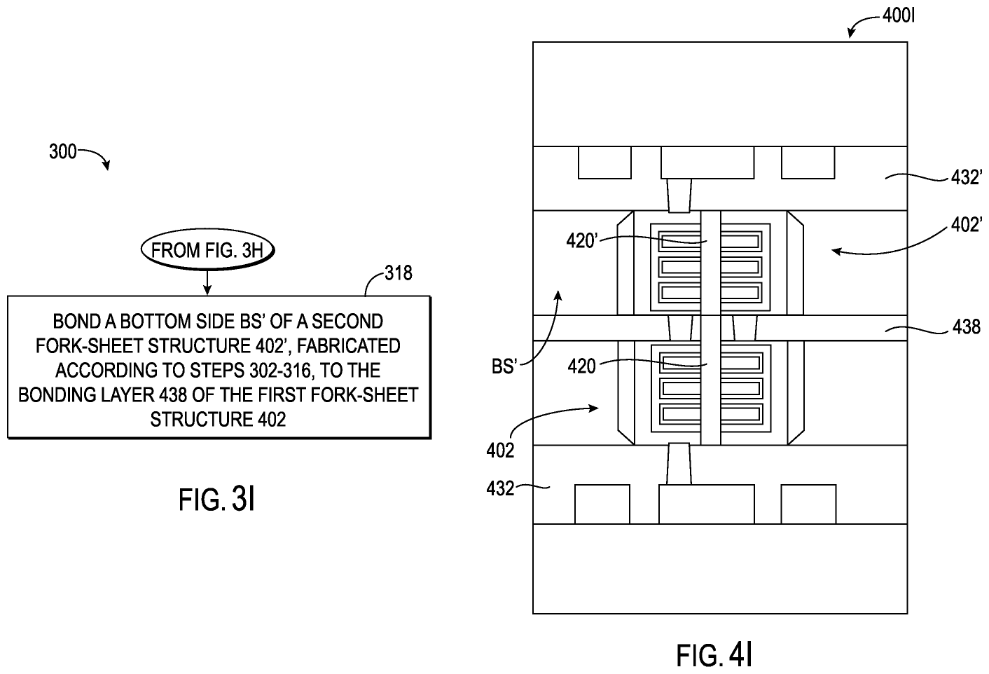

In this regard, FIGS. 3A-3I are a flowchart illustrating another exemplary fabrication process 300 of fabricating a dual circuit structure, including a 3D forksheet stack in which two CMOS circuits are formed in a reduced area including but not limited to the dual circuit structure 100 in FIGS. 1A-1C. FIGS. 4A-4I are exemplary fabrication stages 400A-400I during the dual circuit structure fabrication, including a 3D forksheet stack in which two CMOS circuits are formed in a reduced area according to the fabrication process 300 in FIGS. 3A-3I.

In this regard, as shown in the fabrication stage 400A in FIG. 4A, a first step 302 in the fabrication process 300 includes forming a first forksheet structure 402 on a substrate 404, the first forksheet structure 402 comprising at least one first semiconductor slab 406 stacked in a first, Z-axis direction and surrounded by a dummy poly gate 408, and forming spacers 410 on each side of the dummy poly gate 408. The at least one first semiconductor slab 406 is formed of a semiconductor material, such as Si. The dummy poly gate 408 may be formed of a polysilicon material. The spacers 410 may be SiN, for example.

As shown in the fabrication stage 400B in FIG. 4B, a next step 304 in the fabrication process 300 includes forming a dielectric layer 412 around the first forksheet structure 402, forming a dividing wall mask 414 comprising an opening 416 on the first forksheet structure 402, and forming a trench 418 in the first forksheet structure 402 through the opening 416. For example, the dielectric layer 412 may be an inter-layer dielectric (ILD) material formed on the substrate 404 around the first forksheet structure 402. The first forksheet structure 402 and the dielectric layer 412 may be planarized by a chemical and/or mechanical polish (CMP) before forming the dividing wall mask 414. The trench 418, corresponding to the opening 416, extends through the first forksheet structure 402 in the first Z-axis direction to the substrate 404.

As shown in the fabrication stage 400C in FIG. 4C, a next step 306 in the fabrication process 300 includes forming a dividing wall 420 in the trench 418 of the first forksheet structure 402 and removing the dividing wall mask 414. For example, the dividing wall 420 may be formed of SiN deposited into the trench 418 and chemical and/or mechanical polish (CMP).

As shown in the fabrication stage 400D in FIG. 4D, a next step 308 in the fabrication process 300 includes removing the dummy poly gate 408, forming a high-K dielectric layer 422 on the at least one first semiconductor slab 406 on a first side S1 and a second side S2 of the dividing wall 420, and forming a first type work function metal layer 424 on the high-K dielectric layer 422 on the first side S1 and the second side S2 of the dividing wall 420. The dummy poly gate 408 may be removed by a chemical etch process. The first type of work function metal 424 may be an N-type or a P-type work function metal.

As shown in the fabrication stage 400E in FIG. 4E, a next optional processing step 310 in the fabrication process 300 includes removing the first type work function metal 424 from the semiconductor slabs 406 on the first side S1 of the dividing wall 420 and forming a second type work function metal 426 on the high-K dielectric layer 422 on the at least one first semiconductor slab 406 on the first side S1 of the dividing wall 420. The first type of work function metal 424, may be removed by forming a mask on the second side S2 of the dividing wall and performing a chemical etch.

As shown in the fabrication stage 400F in FIG. 4F, a next step 312 in the fabrication process 300 includes forming a first gate 428 on the work function metal 424, 426 on the first side S1 of the dividing wall 420 and forming a second gate 430 on the first work function metal 424 on the second side S2 of the dividing wall 420. If the first type work function metal 424 is removed from the first side S1 and replaced with the second type work function metal 426, the first gate 428 is formed on the second type work function metal 426 on the side S1. Otherwise, the first gate 428 is formed on the first type work function metal 424 on the side S1.

As shown in the fabrication stage 400G in FIG. 4G, a next step 314 in the fabrication process 300 includes forming a first contact layer 432 on the first dielectric layer 412 and the first forksheet structure 402 and forming a first gate contact 434 coupled to one of the first gate 428 and the second gate 430 through the first contact layer 432. The first contact layer 432 may be formed of an inter-metal dielectric material. The first gate contact 434 may be metal, such as tungsten or copper.

As shown in the fabrication stage 400H in FIG. 4H, a step 316 in the fabrication process 300 includes mounting a carrier wafer 436 on the first contact layer 432, removing the substrate 404 from a bottom side BS of the first forksheet structure 402, and forming a bonding layer 438 optionally comprising inter-gate contacts 440 coupled to the first gate 428 and the second gate 430 on the bottom side BS of the first forksheet structure 402. In examples in which the bonding layer 438 is formed without inter-gate contacts 440, the first gate contact 434 in the first contact layer 432 is coupled to one of the first gate 428 and the second gate 430, and the bonding layer 438 may also include a second gate contact (not shown) that is coupled to the other one of the first gate 428 and the second gate 430.

As shown in the fabrication stage 400I in FIG. 4I, a step 318 in the fabrication process 300 includes bonding a bottom side BS' of a second forksheet structure 402′ fabricated according to steps 302-316, as shown in fabrication stages 400A-400H to the bonding layer 438 of the first forksheet structure 402. In this regard, the second forksheet structure 402′ is disposed on a first side of (e.g., below), in the first Z-axis direction, the first forksheet structure 402 to form a 3D forksheet stack. The dividing walls 420 and 420′ of the first forksheet structure 402 and the second forksheet structure 402′ are aligned to form a single dividing wall 420 extending in the first direction from the first contact layer 432 of the first forksheet structure 402 to the first contact layer 432′ of the second forksheet structure 402′.

Additional examples of cross-sectional views of dual circuit structures, including a 3D forksheet stack in which two CMOS circuits are formed in a reduced area, are presented in FIGS. 5-7. Features of FIGS. 5-7 that are common to FIGS. 1A-1C are labeled alike and may not be described again here.

FIG. 5 is an example of a 3D dual circuit structure 500, including a 3D forksheet structure 502 in which CMOS circuits 504A and 504B are formed in a reduced area. In FIG. 5, the first semiconductor type PN1 of the first portion 110A is opposite to the third semiconductor type PN3 in the third portion 128A in this example. In addition, the second semiconductor type PN2 of the second portion 110B is opposite to the fourth semiconductor type PN4 in the fourth portion 128B in this example. Therefore, transistors (not shown) formed in the first portion 110A and the third portion 128A may form a CMOS circuit 504A, and transistors formed in the second portion 110B and the fourth portion 128B may form a CMOS circuit 504B. On the first side S1 of the dividing wall 106, the first gate 112A in the first portion 110A is coupled to the third gate 130A in the third portion 128A by a first inter-gate contact 506A in the bonding layer 124 forming CMOS circuit 504A, and the second gate 112B in the second portion 110B is coupled to the fourth gate 130B in the fourth portion 128B by a second inter-gate contact 506B on the second side S2 of the dividing wall 106 to form the CMOS circuit 504B.

Including the inter-gate contacts 506A and 506B, as in this example, allows a controlling voltage for the CMOS circuits on each side S1 and S2 of the dividing wall 106 to be provided by the inter-gate contacts 506A, on the first contact layer 148 above (in the Z-axis direction) the first forksheet structure 102Y. This eliminates the need for bottom contacts or vias to couple the third gate 130A in the third portion 128A and the fourth gate 130B in the fourth portion 128B to a controlling voltage.

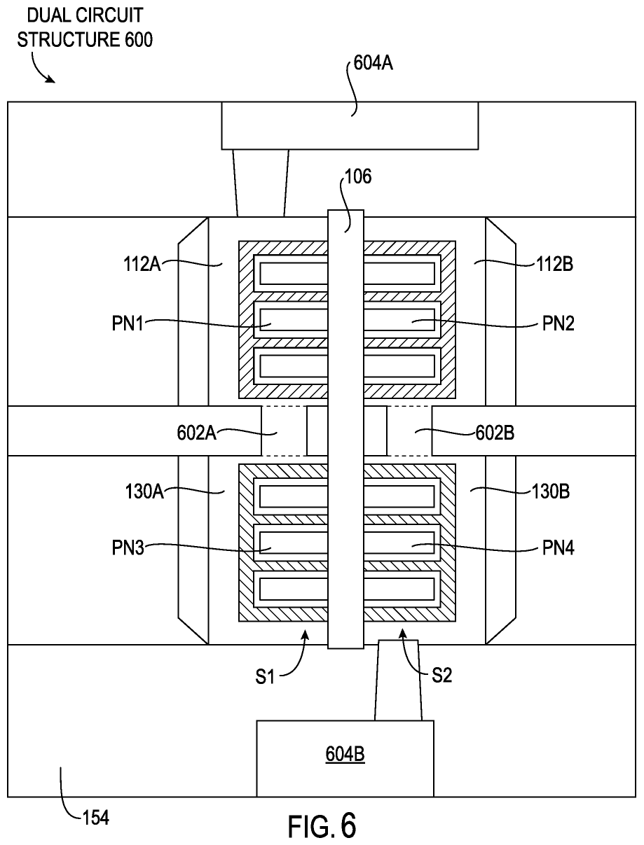

Like the example in FIG. 5, the example of dual circuit structure 600 in FIG. 6 includes inter-gate contacts 602A and 602B to couple the first gate 112A to the third gate 130A on the first side S1 and couple the second gate 112B to the fourth gate 130B in the fourth portion 128B. However, the first contact layer 148 contains only a gate contact 604A coupled to the first gate 112A and the third gate 130A to provide a voltage to the CMOS circuit on first side S1. The second contact layer 154 contains a gate contact 604B coupled to the fourth gate 130B and the second gate 112B to provide a voltage to the CMOS circuit on the second side S2.

The second semiconductor type PN2 and the fourth semiconductor type PN4 are opposite to each other, as in FIG. 5, but in the dual circuit structure 600, the second semiconductor type PN2 and the first semiconductor PN1 in the first forksheet structure 102Y has the same semiconductor type (as each other) and the fourth semiconductor type PN4 and the third semiconductor type PN3 in the second forksheet structure 102X have the same semiconductor type. Thus, the dual circuit structure 600 in FIG. 6 may provide the same CMOS circuits as the dual circuit structure 500 in FIG. 5 but does not require the optional processing step 310 in the process 300 of forming opposite semiconductor types on different sides S1 and S2 of the dividing wall 106.

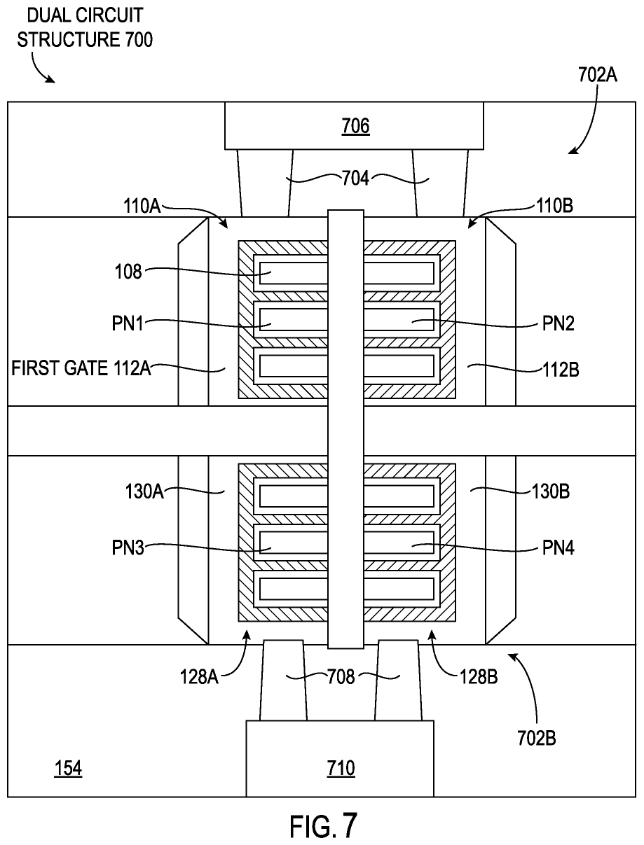

FIG. 7 shows another example of a dual circuit structure 700, including a 3D forksheet structure in which CMOS circuits 702A and 702B are formed in a reduced area. The first semiconductor type PN1 in the first portion 110A of the at least one semiconductor slab 108 is opposite to the second semiconductor type PN2 in the second portion 110B. In addition, the first gate 112A and the second gate 112B are coupled to each other in the first contact layer 148 by vias 704 and contact 706. In contrast to FIGS. 5 and 6, in which CMOS circuits are formed on each side of the dividing wall 106, the dual circuit structure in FIG. 7 implements CMOS circuits 702A and 702B on each side of the bonding layer 124. For example, the first gate 112A and the second gate 112B are coupled to form a CMOS inverter. Similarly, the third semiconductor type PN3 is opposite to the fourth semiconductor type PN4, and the gates 130A and 130B are coupled to each other through vias 708 and contact 710 in the second contact layer 154.

It should be understood that, in all the examples in FIGS. 5-7, the source/drain regions may also be coupled to an external circuit or another terminal through vias and contacts in the first contact layer 148 and the second contact layer 154.

Electronic devices that include 3D dual complementary-circuit structures, including stacked forksheet structures in which two CMOS circuits are formed in a reduced area, as illustrated in FIGS. 1A-1C and 5-7, and according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

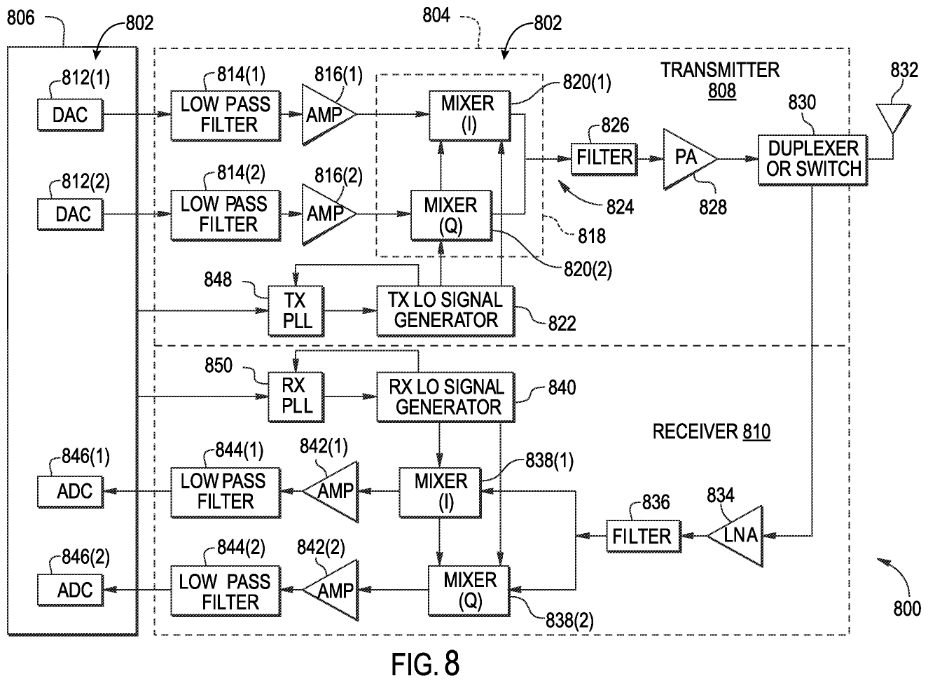

In this regard, FIG. 8 illustrates an exemplary wireless communications device 800 that includes radio frequency (RF) components formed from one or more ICs 802, wherein any of the ICs 802 can include integrated circuits, including dual complementary-circuit structures, including stacked forksheet structures in which two CMOS circuits are formed in an area of a single forksheet, as illustrated in FIGS. 1A-1C and 5-7, and according to any aspects disclosed herein. The wireless communications device 800 may include or be provided as examples in any of the above-referenced devices. As shown in FIG. 8, the wireless communications device 800 includes a transceiver 804 and a data processor 806. The data processor 806 may include a memory to store data and program codes. The transceiver 804 includes a transmitter 808 and a receiver 810, which support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals from a TX LO signal generator 822 through mixers 820(1), 820(2) to provide an upconverted signal 824. A filter 826 filters the upconverted signal 824 to remove undesired signals caused by the frequency upconversion and noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

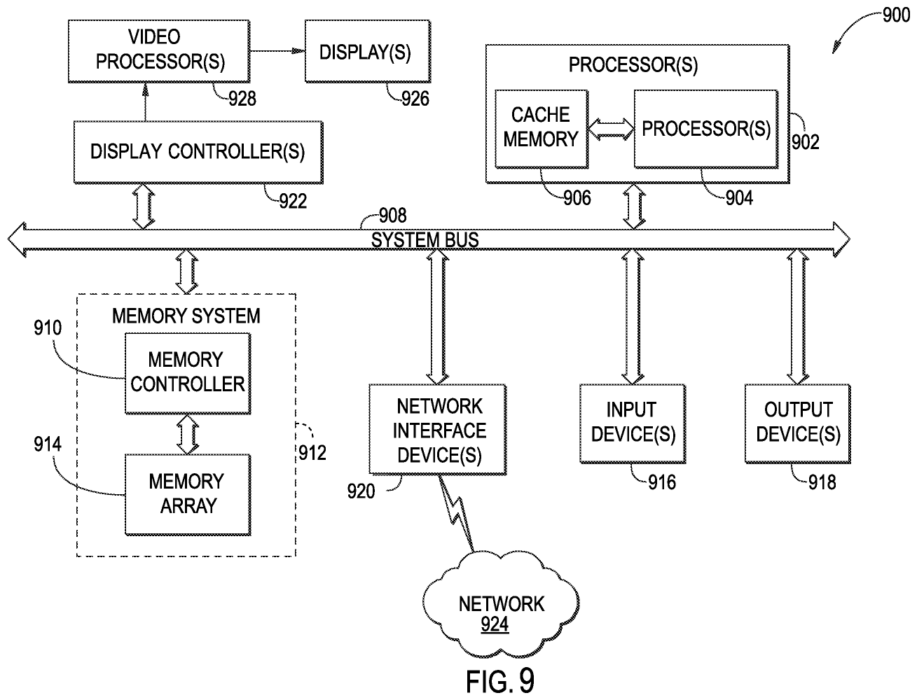

FIG. 9 illustrates an example of a processor-based system 900 that can employ integrated circuits, including dual complementary-circuit structures and stacked forksheet structures in which two CMOS circuits are formed in an area of a single forksheet, as illustrated in FIGS. 1A-1C and 5-7. In this example, the processor-based system 900 includes one or more central processor units (CPUs) 902, which may also be referred to as CPU or processor cores, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory controller 910 as an example of a slave device. Although not illustrated in FIG. 9, multiple system buses 908 could be provided wherein each system bus 908 constitutes a different fabric.

Other master and slave devices can be connected to the system bus 908. As illustrated in FIG. 9, these devices can include a memory system 912 that includes the memory controller 910 and one or more memory arrays 914, one or more input devices 916, one or more output devices 918, one or more network interface devices 920, and one or more display controllers 922, as examples. The input device(s) 916 can include any type of input device, including, but not limited to, input keys, switches, voice processors, etc. The output device(s) 918 can include any type of output device, including, but not limited to, audio, video, other visual indicators, etc. The network interface device(s) 920 can be any device configured to allow an exchange of data to and from a network 924. The network 924 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 920 can be configured to support any type of communications protocol desired.

The CPU(s) 902 may also be configured to access the display controller(s) 922 over the system bus 908 to control information sent to one or more displays 926. The display controller(s) 922 sends information to the display(s) 926 to be displayed via one or more video processors 928, which process the information to be displayed into a format suitable for the display(s) 926. The display(s) 926 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A three-dimensional (3D) dual circuit structure, comprising:
   a first forksheet structure comprising at least one first semiconductor slab;
   a second forksheet structure comprising at least one second semiconductor slab and disposed on a first side of, in a first direction, the first forksheet structure; and
   a dividing wall bisecting each of the at least one first semiconductor slab and the at least one second semiconductor slab in a second direction orthogonal to the first direction,
   wherein:
      the first semiconductor slab bisected by the dividing wall comprises a first slab portion comprising a first semiconductor type on a first side of the dividing wall and a second slab portion comprising a second semiconductor type on a second side of the dividing wall;
      the second semiconductor slab bisected by the dividing wall comprises a third slab portion comprising a third semiconductor type on the first side of the dividing wall and a fourth slab portion comprising a fourth semiconductor type on the second side of the dividing wall; and
      a first one of the second semiconductor type, the third semiconductor type, and the fourth semiconductor type is the same semiconductor type as the first semiconductor type.
2. The 3D dual circuit structure of clause 1, wherein:
   a second one of the second semiconductor type, the third semiconductor type, and the fourth semiconductor type is the same semiconductor type as a third one of the second semiconductor type, the third semiconductor type, and the fourth semiconductor type.
3. The 3D dual circuit structure of clause 1 or clause 2, wherein the second semiconductor type is the first one of the second semiconductor type, the third semiconductor type, and the fourth semiconductor type.
4. The 3D dual circuit structure of clause 1 or clause 2, wherein the third semiconductor type is the first one of the second semiconductor type, the third semiconductor type, and the fourth semiconductor type.
5. The 3D dual circuit structure of clause 1 or clause 2, wherein the fourth semiconductor type is the first one of the second semiconductor type, the third semiconductor type, and the fourth semiconductor type.
6. The 3D dual circuit structure of any one of clause 1 to clause 5, the first forksheet structure further comprising:
   a first gate; and
   a second gate;
   wherein:
      the first gate is disposed around the at least one first semiconductor slab in the first slab portion;
      the second gate is disposed around the at least one first semiconductor slab in the second slab portion; and
      the first gate is separated from the second gate by the dividing wall.
7. The 3D dual circuit structure of clause 6, the second forksheet structure further comprising:
   a third gate; and
   a fourth gate;
   wherein:
      the third gate is disposed around the at least one second semiconductor slab in the third slab portion;
      the fourth gate is disposed around the at least one second semiconductor slab in the fourth slab portion; and
      the third gate is separated from the fourth gate by the dividing wall.
8. The 3D dual circuit structure of clause 6 or clause 7, further comprising:
   a first type work function metal disposed between the first gate and the at least one first semiconductor slab in the first slab portion; and
   the first type work function metal disposed in a first one of the second slab portion, the third slab portion, and the fourth slab portion comprising the first one of the second semiconductor type, the third semiconductor type, and the fourth semiconductor type.
9. The 3D dual circuit structure of clause 8, further comprising:
   a second type work function metal, different from the first type work function metal, disposed in a second one and a third one of the second slab portion, the third slab portion, and the fourth slab portion.
10. The 3D dual circuit structure of clause 7, further comprising a bonding layer, wherein:
   the first forksheet structure is disposed in a first dielectric layer;
   the second forksheet structure is disposed in a second dielectric layer; and
   the bonding layer is disposed between the first dielectric layer and the second dielectric layer.
11. The 3D dual circuit structure of clause 10, the bonding layer further comprising:
   a first inter-gate contact electrically coupling the first gate to the third gate; and
   a second inter-gate contact electrically coupling the second gate to the fourth gate.
12. The 3D dual circuit structure of clause 10 or clause 11, wherein the dividing wall extends through the bonding layer.
13. The 3D dual circuit structure of any one of clause 7 to clause 12, further comprising:
   a first contact layer disposed on the first forksheet structure, the first contact layer comprising:
      a first gate contact coupled to the first gate; and
      a second gate contact coupled to the second gate; and
   a second contact layer disposed on the second forksheet structure, the second contact layer comprising:
      a third gate contact coupled to the third gate; and
      a fourth gate contact coupled to the fourth gate.
14. The 3D dual circuit structure of clause 13, further comprising:
   a first source/drain coupled to each of the at least one first semiconductor slab in the first slab portion on a first side of the first gate;
   a second source/drain coupled to each of the at least one first semiconductor slab in the first slab portion on a second side of the first gate;
   a third source/drain coupled to each of the at least one first semiconductor slab in the second slab portion on a first side of the second gate;
   a fourth source/drain coupled to each of the at least one first semiconductor slab in the second slab portion on a second side of the second gate;
   a fifth source/drain coupled to each of the at least one second semiconductor slab in the third slab portion on a first side of the third gate;
   a sixth source/drain coupled to each of the at least one second semiconductor slab in the third slab portion on a second side of the third gate;
   a seventh source/drain coupled to each of the at least one second semiconductor slab in the fourth slab portion on a first side of the fourth gate; and
   an eighth source/drain coupled to each of the at least one second semiconductor slab in the fourth slab portion on a second side of the fourth gate.
15. The 3D dual circuit structure of clause 14, wherein:
   the first contact layer further comprising:
      a first source/drain contact coupled to the first source/drain;
      a second source/drain contact coupled to the second source/drain;
      a third source/drain contact coupled to the third source/drain; and
      a fourth source/drain contact coupled to the fourth source/drain; and
   the second contact layer further comprising:
      a fifth source/drain contact coupled to the fifth source/drain;
      a sixth source/drain contact coupled to the sixth source/drain;
      a seventh source/drain contact coupled to the seventh source/drain; and
      an eighth source/drain contact coupled to the eighth source/drain.
16. The 3D dual circuit structure of clause 15, further comprising:
   a first via coupling the first source/drain contact to the fifth source/drain contact; and
   a second via coupling the third source/drain contact to the seventh source/drain contact.
17. The 3D dual circuit structure of clause 10 or clause 12, wherein:
   the first gate is electrically isolated from the third gate by the bonding layer; and
   the second gate is electrically isolated from the fourth gate by the bonding layer.
18. The 3D dual circuit structure of any one of clause 1 to clause 17 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
19. A method of fabricating a 3D dual circuit structure, the method comprising:
   forming a first forksheet structure comprising at least one first semiconductor slab;
   forming a second forksheet structure comprising at least one second semiconductor slab and disposed on a first side of, in a first direction, the first forksheet structure; and
   forming a dividing wall bisecting the at least one first semiconductor slab and the at least one second semiconductor slab in a second direction, orthogonal to the first direction,
   wherein:
      the first semiconductor slab bisected by the dividing wall comprises a first slab portion comprising a first semiconductor type on a first side of the dividing wall and a second slab portion comprising a second semiconductor type on a second side of the dividing wall;
      the second semiconductor slab bisected by the dividing wall comprises a third slab portion comprising a third semiconductor type on the first side of the dividing wall and a fourth slab portion comprising a fourth semiconductor type on the second side of the dividing wall; and
      a first one of the second semiconductor type, the third semiconductor type, and the fourth semiconductor type is the same semiconductor type as the first semiconductor type.
20. An integrated circuit (IC) comprising:
   complementary logic circuits comprising a plurality of 3D dual circuit structures, each of the 3D dual circuit structures comprising:
      a first forksheet structure comprising at least one first semiconductor slab;
      a second forksheet structure comprising at least one second semiconductor slab, and disposed on a first side of, in a first direction, the first forksheet structure; and
      a dividing wall bisecting the at least one first semiconductor slab in a second direction orthogonal to the first direction into a first slab portion comprising a first semiconductor type on a first side of the dividing wall and a second slab portion comprising a second semiconductor type on a second side of the dividing wall and bisecting the at least one second semiconductor slab in the second direction into a third slab portion comprising a third semiconductor type on the first side of the dividing wall and a fourth slab portion comprising a fourth semiconductor type on the second side of the dividing wall,
      wherein:
         a first one of the second semiconductor type, the third semiconductor type, and the fourth semiconductor type is the same semiconductor type as the first semiconductor type.

What is claimed is:

1. A three-dimensional (3D) dual circuit structure, comprising:
a first forksheet structure comprising at least one first semiconductor slab;
a second forksheet structure comprising at least one second semiconductor slab and disposed on a first side of, in a first direction, the first forksheet structure; and
a dividing wall bisecting each of the at least one first semiconductor slab and the at least one second semiconductor slab in a second direction orthogonal to the first direction,
wherein:
the first semiconductor slab bisected by the dividing wall comprises a first slab portion comprising a first semiconductor type on a first side of the dividing wall and a second slab portion comprising a second semiconductor type on a second side of the dividing wall;
the second semiconductor slab bisected by the dividing wall comprises a third slab portion comprising a third semiconductor type on the first side of the dividing wall and a fourth slab portion comprising a fourth semiconductor type on the second side of the dividing wall; and
a first one of the second semiconductor type, the third semiconductor type, and the fourth semiconductor type is the same semiconductor type as the first semiconductor type.

2. The 3D dual circuit structure of claim 1, wherein:
a second one of the second semiconductor type, the third semiconductor type, and the fourth semiconductor type is the same semiconductor type as a third one of the second semiconductor type, the third semiconductor type, and the fourth semiconductor type.

3. The 3D dual circuit structure of claim 1, wherein the second semiconductor type is the first one of the second semiconductor type, the third semiconductor type, and the fourth semiconductor type.

4. The 3D dual circuit structure of claim 1, wherein the third semiconductor type is the first one of the second semiconductor type, the third semiconductor type, and the fourth semiconductor type.

5. The 3D dual circuit structure of claim 1, wherein the fourth semiconductor type is the first one of the second semiconductor type, the third semiconductor type, and the fourth semiconductor type.

6. The 3D dual circuit structure of claim 1, the first forksheet structure further comprising:
a first gate; and
a second gate;
wherein:
the first gate is disposed around the at least one first semiconductor slab in the first slab portion;
the second gate is disposed around the at least one first semiconductor slab in the second slab portion; and
the first gate is separated from the second gate by the dividing wall.

7. The 3D dual circuit structure of claim 6, the second forksheet structure further comprising:
a third gate; and
a fourth gate;
wherein:
the third gate is disposed around the at least one second semiconductor slab in the third slab portion;
the fourth gate is disposed around the at least one second semiconductor slab in the fourth slab portion; and
the third gate is separated from the fourth gate by the dividing wall.

8. The 3D dual circuit structure of claim 6, further comprising:
a first type work function metal disposed between the first gate and the at least one first semiconductor slab in the first slab portion; and
the first type work function metal disposed in a first one of the second slab portion, the third slab portion, and the fourth slab portion comprising the first one of the second semiconductor type, the third semiconductor type, and the fourth semiconductor type.

9. The 3D dual circuit structure of claim 8, further comprising:
a second type work function metal, different from the first type work function metal, disposed in a second one and a third one of the second slab portion, the third slab portion, and the fourth slab portion.

10. The 3D dual circuit structure of claim 7, further comprising a bonding layer, wherein:
the first forksheet structure is disposed in a first dielectric layer;
the second forksheet structure is disposed in a second dielectric layer; and
the bonding layer is disposed between the first dielectric layer and the second dielectric layer.

11. The 3D dual circuit structure of claim 10, the bonding layer further comprising:
a first inter-gate contact electrically coupling the first gate to the third gate; and
a second inter-gate contact electrically coupling the second gate to the fourth gate.

12. The 3D dual circuit structure of claim 10, wherein the dividing wall extends through the bonding layer.

13. The 3D dual circuit structure of claim 7, further comprising:
a first contact layer disposed on the first forksheet structure, the first contact layer comprising:
a first gate contact coupled to the first gate; and
a second gate contact coupled to the second gate; and
a second contact layer disposed on the second forksheet structure, the second contact layer comprising:
a third gate contact coupled to the third gate; and
a fourth gate contact coupled to the fourth gate.

14. The 3D dual circuit structure of claim 13, further comprising:
a first source/drain coupled to each of the at least one first semiconductor slab in the first slab portion on a first side of the first gate;
a second source/drain coupled to each of the at least one first semiconductor slab in the first slab portion on a second side of the first gate;
a third source/drain coupled to each of the at least one first semiconductor slab in the second slab portion on a first side of the second gate;
a fourth source/drain coupled to each of the at least one first semiconductor slab in the second slab portion on a second side of the second gate;
a fifth source/drain coupled to each of the at least one second semiconductor slab in the third slab portion on a first side of the third gate;
a sixth source/drain coupled to each of the at least one second semiconductor slab in the third slab portion on a second side of the third gate;
a seventh source/drain coupled to each of the at least one second semiconductor slab in the fourth slab portion on a first side of the fourth gate; and
an eighth source/drain coupled to each of the at least one second semiconductor slab in the fourth slab portion on a second side of the fourth gate.

15. The 3D dual circuit structure of claim 14, wherein:
the first contact layer further comprising:
a first source/drain contact coupled to the first source/drain;
a second source/drain contact coupled to the second source/drain;
a third source/drain contact coupled to the third source/drain; and
a fourth source/drain contact coupled to the fourth source/drain; and
the second contact layer further comprising:
a fifth source/drain contact coupled to the fifth source/drain;
a sixth source/drain contact coupled to the sixth source/drain;
a seventh source/drain contact coupled to the seventh source/drain; and
an eighth source/drain contact coupled to the eighth source/drain.

16. The 3D dual circuit structure of claim 15, further comprising:
a first via coupling the first source/drain contact to the fifth source/drain contact; and
a second via coupling the third source/drain contact to the seventh source/drain contact.

17. The 3D dual circuit structure of claim 10, wherein:
the first gate is electrically isolated from the third gate by the bonding layer; and
the second gate is electrically isolated from the fourth gate by the bonding layer.

18. The 3D dual circuit structure of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

19. A method of fabricating a 3D dual circuit structure, the method comprising:
forming a first forksheet structure comprising at least one first semiconductor slab;
forming a second forksheet structure comprising at least one second semiconductor slab and disposed on a first side of, in a first direction, the first forksheet structure; and
forming a dividing wall bisecting the at least one first semiconductor slab and the at least one second semiconductor slab in a second direction, orthogonal to the first direction,
wherein:
the first semiconductor slab bisected by the dividing wall comprises a first slab portion comprising a first semiconductor type on a first side of the dividing wall and a second slab portion comprising a second semiconductor type on a second side of the dividing wall;
the second semiconductor slab bisected by the dividing wall comprises a third slab portion comprising a third semiconductor type on the first side of the dividing wall and a fourth slab portion comprising a fourth semiconductor type on the second side of the dividing wall; and
a first one of the second semiconductor type, the third semiconductor type, and the fourth semiconductor type is the same semiconductor type as the first semiconductor type.

20. An integrated circuit (IC) comprising:
complementary logic circuits comprising a plurality of 3D dual circuit structures, each of the 3D dual circuit structures comprising:
a first forksheet structure comprising at least one first semiconductor slab;
a second forksheet structure comprising at least one second semiconductor slab, and disposed on a first side of, in a first direction, the first forksheet structure; and
a dividing wall bisecting the at least one first semiconductor slab in a second direction orthogonal to the first direction into a first slab portion comprising a first semiconductor type on a first side of the dividing wall and a second slab portion comprising a second semiconductor type on a second side of the dividing wall and bisecting the at least one second semiconductor slab in the second direction into a third slab portion comprising a third semiconductor type on the first side of the dividing wall and a fourth slab portion comprising a fourth semiconductor type on the second side of the dividing wall,
wherein:
a first one of the second semiconductor type, the third semiconductor type, and the fourth semiconductor type is the same semiconductor type as the first semiconductor type.
